(19) United States
(12) Patent Application Publication
(10) Pub. No.: US 2024/0222588 A1
(43) Pub. Date: Jul. 4, 2024

(54) SEMICONDUCTOR LIGHT-EMITTING ELEMENT AND LIGHT-EMITTING DEVICE THEREOF

(71) Applicant: Tianjin Sanan Optoelectronics Co., Ltd., Tianjin (CN)

(72) Inventors: Weiping XIONG, Tianjin (CN); Di GAO, Tianjin (CN); Zhiwei WU, Tianjin (CN); Huanshao KUO, Tianjin (CN); Yuren PENG, Tianjin (CN); Shutian QIU, Tianjin (CN)

(21) Appl. No.: 18/491,825

(22) Filed: Oct. 23, 2023

(30) Foreign Application Priority Data
Dec. 29, 2022 (CN) 2022117280983

(51) Int. Cl. H01L 33/62; H01L 25/075; H01L 33/22

(52) U.S. Cl. CPC H01L 33/62; H01L 25/0753; H01L 33/22

(57) ABSTRACT

A semiconductor light-emitting element and a light-emitting device thereof are provided. The semiconductor light-emitting element includes a transparent substrate, a transparent bonding layer, and a semiconductor laminated layer including a first semiconductor layer, a light-emitting layer, and a second semiconductor layer. The transparent bonding layer is located between the transparent substrate and the semiconductor laminated layer. The transparent substrate has a first surface facing towards the semiconductor laminated layer, and the first surface has an uneven structure. The semiconductor laminated layer has a first surface facing towards the transparent substrate. The transparent bonding layer includes a first bonding layer in contact with the first surface of the transparent substrate, and a refractive index of the first bonding layer is lower than that of the transparent substrate. By utilizing the optimized design, the quality of bonding is ensured while improving the light extraction efficiency of the semiconductor light-emitting element.

### TECHNICAL FIELD

The disclosure relates to the field of semiconductor optoelectronic devices and technologies, and more particularly to a semiconductor light-emitting element with a transparent bonding layer and a light-emitting device thereof.

### BACKGROUND

Flip-chip light-emitting diodes (LEDs) are an effective technical means to further improve the luminous efficiency of light-emitting diodes due to their advantages of no wire bonding, no electrode shading, and excellent heat dissipation. At present, aluminum gallium indium phosphide (AlGaInP) quaternary materials used for manufacturing high-power and high-brightness red and yellow LEDs mainly use light-absorbing gallium arsenic (GaAs) substrate materials, and in order to make a high-brightness flip-chip LED, it is necessary to transfer LED to a transparent substrate and effectively extract light to improve external quantum efficiency.

As illustrated in FIG. 1, FIG. 1 is a schematic structural diagram of a flip-chip light-emitting element in the related art. The flip-chip light-emitting element includes a transparent substrate 001, a transparent bonding layer 002, and a semiconductor laminated layer arranged from top to bottom. The semiconductor laminated layer includes a first semiconductor layer 004, a light-emitting layer 005, and a second semiconductor layer 006 arranged from top to bottom. An interface between the transparent substrate 001 and the transparent bonding layer 002 is flat, while an interface between the first semiconductor layer 004 and the transparent bonding layer 002 is uneven. The interface between the first semiconductor layer 004 and the transparent bonding layer 002 is designed to be uneven, which can facilitate the effective extraction of light from the semiconductor laminated layer and improve external quantum efficiency.

### SUMMARY

Purposes of the disclosure are to provide a semiconductor light-emitting element and its light-emitting device, utilizing an optimized design of a transparent bonding layer and a transparent substrate to ensure bonding quality while improving the light extraction efficiency of the semiconductor light-emitting element.

According to a first aspect of the disclosure, a semiconductor light-emitting element is provided. The semiconductor light-emitting element includes: a transparent substrate, a transparent bonding layer, and a semiconductor laminated layer. The transparent bonding layer is located between the transparent substrate and the semiconductor laminated layer. The semiconductor laminated layer includes a first semiconductor layer, a light-emitting layer, and a second semiconductor layer. The transparent substrate has a first surface facing towards the semiconductor laminated layer, and the first surface of the transparent substrate has an uneven structure. The transparent bonding layer includes a first bonding layer in contact with the first surface of the transparent substrate, and a refractive index of the first bonding layer is lower than that of the transparent substrate.

According to a second aspect of the disclosure, a semiconductor light-emitting element is provided. The semiconductor light-emitting element includes: a transparent substrate, an intermediate layer, a transparent bonding layer, and a semiconductor laminated layer. The intermediate layer is located between the transparent substrate and the transparent bonding layer; The transparent bonding layer is located between the intermediate layer and the semiconductor laminated layer. The semiconductor laminated layer includes a first semiconductor layer, a light-emitting layer, and a second semiconductor layer. The transparent substrate is a flat substrate, the intermediate layer has a first surface facing towards the semiconductor laminated layer, and the first surface of the intermediate layer has an uneven structure. A refractive index of the intermediate layer is higher than that of the transparent bonding layer.

### BRIEF DESCRIPTION OF DRAWINGS

FIG. 1 illustrates a schematic cross-sectional diagram of a semiconductor light-emitting device with a transparent bonding layer in the related art.

FIG. 2 illustrates a schematic cross-sectional diagram of a semiconductor light-emitting element according to an embodiment 1 of the disclosure.

FIG. 3 illustrates a schematic cross-sectional diagram of a semiconductor light-emitting element according to an embodiment 2 of the disclosure.

FIG. 4 illustrates a schematic cross-sectional diagram of a semiconductor light-emitting element according to an embodiment 3 of the disclosure.

FIG. 5 illustrates a schematic cross-sectional diagram of a semiconductor light-emitting element according to an embodiment 4 of the disclosure.

FIG. 6 illustrates a schematic cross-sectional diagram of a light-emitting device according to an embodiment 5 of the disclosure.

### DETAILED DESCRIPTION OF EMBODIMENTS

### Embodiment 1

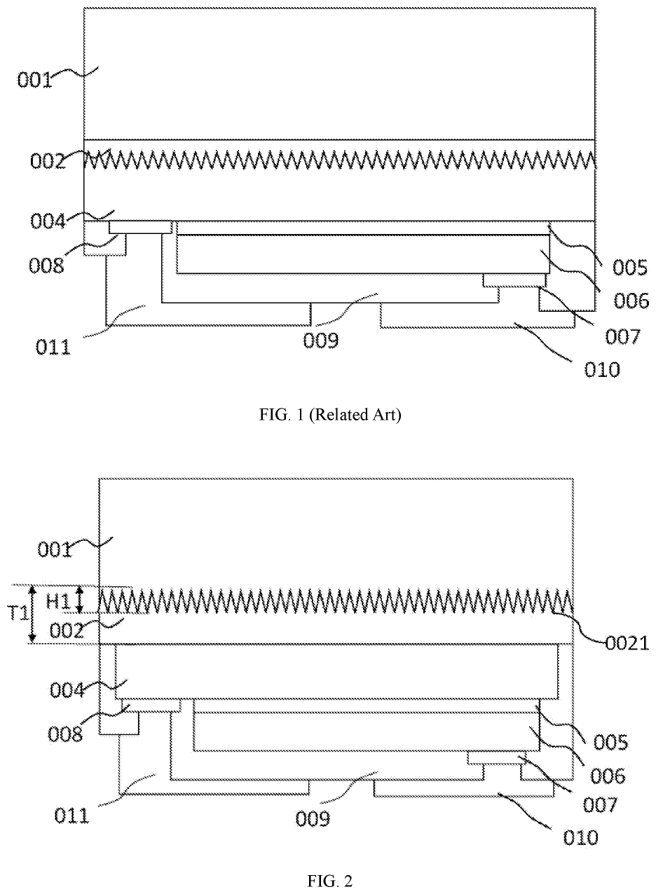

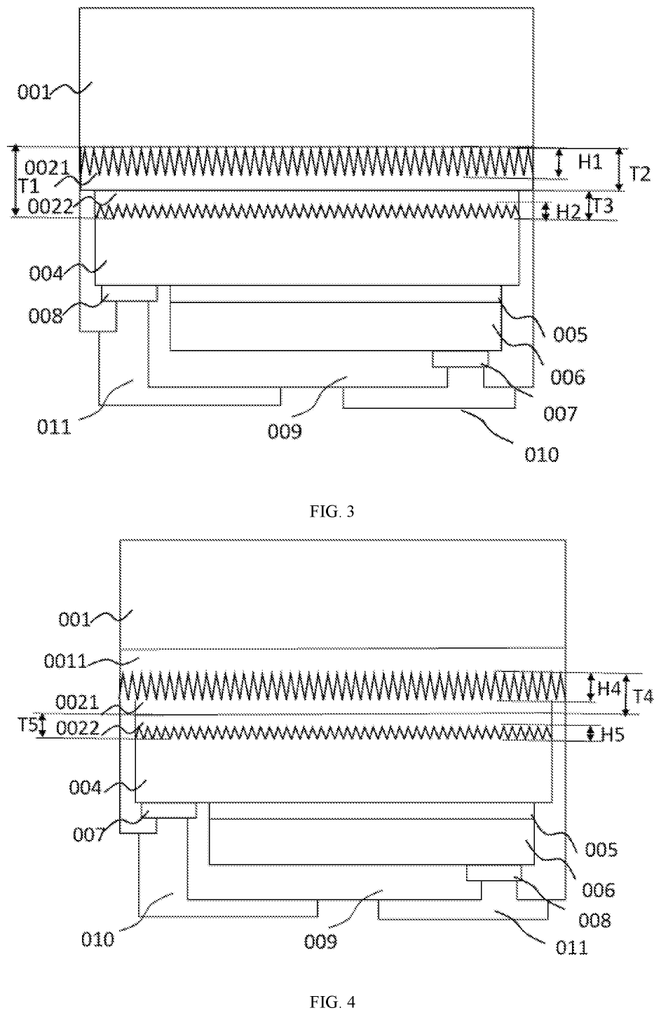

FIG. 2 illustrates a schematic cross-sectional diagram of a semiconductor light-emitting element. The semiconductor light-emitting element is a flip-chip light-emitting element with the characteristic of radiating light energy from an upper surface and side walls of a transparent substrate 001. Specifically, the flip-chip light-emitting element includes the transparent substrate 001, a transparent bonding layer 002, and a semiconductor laminated layer arranged from top to bottom. The semiconductor laminated layer includes a first semiconductor layer 004, a light-emitting layer 005, and a second semiconductor layer 006 arranged from top to bottom.

The transparent substrate 001 has a first surface and a second surface opposite to each other, and side walls connecting the first surface and the second surface. The first surface of the transparent substrate 001 is a lower surface, the first surface of the transparent substrate 001 is facing towards the semiconductor laminated layer, and the second surface is an upper surface facing away from the semiconductor laminated layer as a top surface of the flip-chip light-emitting element. The upper surface and the side walls of the transparent substrate 001 can transmit light to provide an interface for emitting light from the flip-chip light-emitting element.

The transparent bonding layer 002 is located between the semiconductor laminated layer and the first surface of the transparent substrate 001, and has transparency (i.e., transmittance) to the light of the semiconductor laminated layer.

The transparent bonding layer 002 includes at least one first bonding layer 0021, and the first bonding layer 0021 is in contact with the first surface of the transparent substrate 001.

In an embodiment, the first bonding layer 0021 is a silicon oxide layer (with a refractive index of about 1.5), and the material of the transparent substrate 001 is a sapphire substrate (with a refractive index of about 1.7). The transparency and interface adhesion of the first bonding layer 0021 and the transparent substrate 001 are great, and a refractive index of the silicon oxide layer is lower than that of the semiconductor laminated layer, which is conducive to the output of light from the semiconductor laminated layer and improves the efficiency of light extraction.

However, due to the lower refractive index of the first bonding layer 0021 compared to the transparent substrate, light is easily bound when outputting from the interface of the first bonding layer 0021 to the transparent substrate 001. When light reaches the interface between sapphire and air from inside the sapphire substrate, due to the lower refractive index of air compared to the sapphire, light is easily reflected back and forth inside the transparent substrate.

Therefore, the first surface of the transparent substrate 001 proposed by the disclosure has an uneven structure. By utilizing the uneven structure of the transparent substrate 001, a change in a direction of light can be achieved when light is emitted to the interface between the first bonding layer 0021 and the transparent substrate 001, increasing the probability of emitting from the side walls of the transparent substrate, thereby increasing the output efficiency of light and enhancing brightness.

In an embodiment, the uneven structure on the upper surface of the transparent substrate 001 has a regular shape, such as a sharp cone shape, a conical platform shape, a columnar shape, or a random irregular shape, such as a random coarsened structure.

In an embodiment, the transparent substrate 001 is sapphire, which has high hardness and strong chemical stability, but its etching difficulty is relatively high. Therefore, the uneven structure on the sapphire substrate can be obtained through photoresist pattern assisted dry etching or wet etching, and the uneven structure can be defined to have a regular shape with uniform appearance according to the photoresist pattern, including a uniform and consistent height, width, shape, and spacing.

The shape of the uneven structure of the first surface of the transparent substrate 001 can be a sharp cone shape or a conical platform shape. When the side walls of the transparent substrate 001 are designed with an inclined direction relative to a horizontal direction, it is more advantageous to change the direction of light, and the horizontal direction is perpendicular to the laminated direction of each layer.

In an embodiment, a thickness of the transparent substrate 001 can be 40-150 micrometers. In a specific embodiment, the thickness of the transparent substrate 001 is 60-100 micrometers.

In an embodiment, the height H1 of the uneven structure of the first surface of the transparent substrate 001 is 0.1-3 micrometers. In a specific embodiment, the height H1 is 0.5-2.5 micrometers. In another specific embodiment, the height H1 is 1.5-2.5 micrometers. A spacing between adjacent patterns is 0.1-3 micrometers. In a specific embodiment, the spacing between adjacent patterns is 2-3 micrometers. A bottom width is 0.1-4 micrometers. In a specific embodiment, the bottom width is 1-3 micrometers. That is, the uneven structure of the transparent substrate 001 includes multiple patterned structures arranged in an array. The spacing between adjacent patterned structures is 0.1-3 micrometers, such as 2-3 micrometers. The bottom width of the patterned structure is 0.1-4 micrometers, such as 1-3 micrometers. In addition, utilizing the thicker thickness of the sapphire pattern can achieve a larger size pattern structure, which can significantly change the direction of light, facilitate light output from the side walls of the transparent substrate, and improve light output efficiency.

In an embodiment, the shape of the uneven structure on the first surface of the transparent substrate 001 is a sharp cone shape, and the appearance of the side walls is arc-shaped or polyhedral.

The second surface of the transparent substrate 001 is rectangular or square when viewed from one side of the transparent substrate 001.

The thickness T1 of the first bonding layer 0021 is greater than the height H1 of the uneven structure of the first surface of the transparent substrate 001. In an embodiment, the thickness T1 of the first bonding layer 0021 is 1-4 micrometers, where the thickness T1 of the first bonding layer 0021 refers to the maximum thickness of the first bonding layer 0021.

The first semiconductor layer 004 and the second semiconductor layer 006 have different conductive states, electrical properties, polarity, or at least provide electrons or holes depending on different doping elements. The light-emitting layer 005 is formed between the first semiconductor layer 004 and the second semiconductor layer 006, and can convert electrical energy into light energy. The wavelength of the emitted light is adjusted by changing the physical and chemical composition of one or more of the layers of the semiconductor laminated layer. The commonly used material for forming the semiconductor laminated layer is the aluminum gallium indium phosphide (AlGaInP) series, with a refractive index between 3.0 and 3.5. The light-emitting layer 005 can be a single heterostructure (SH), a double heterostructure (DH), a double-sided double heterostructure (DDH), or a multi-quantum well (MWQ). Specifically, the light-emitting layer 005 can be a neutral, p-type, or n-type electrical semiconductor. When a current is applied to pass through the semiconductor laminated layer, the light-emitting layer 005 emits light. When the material of the light-emitting layer 005 is aluminum indium gallium phosphide (AlGaInP) series, it emits red, orange, yellow, and infrared light.

The semiconductor laminated layer is manufactured using an existing epitaxial method, such as metal-organic chemical vapor deposition (MOCVD), molecular beam epitaxy (MBE), or hydride vapor phase epitaxy (HVPE).

In this embodiment, the material of the semiconductor laminated layer is the aluminum gallium indium phosphide (AlGaInP) series, and the light emitted is red. The first semiconductor layer 004 is doped as p-type and the second semiconductor layer 006 is doped as n-type, at least having a hole injection layer and an electron injection layer.

The semiconductor laminated layer includes a first surface and a second surface, with the first surface and the second surface being an upper surface and a lower surface of the semiconductor laminated layer respectively. The semiconductor laminated layer further includes side walls connecting the first surface and the second surface. In this embodiment, as shown in FIG. 2, as an implementation, the first surface is flat. Specifically, the first bonding layer 0021 is formed on the first surface of the transparent substrate 001 through chemical deposition or coating processes, and is bonded on one side of the first surface of the semiconductor laminated layer through the bonding process. Therefore, the first bonding layer 0021 is in contact with the first surface of the transparent substrate 001 and the first surface of the semiconductor laminated layer.

A first electrode 007 is formed on one side of the second semiconductor layer 006, and a second electrode 008 is formed on one side of the first semiconductor layer 004. The first electrode 007 and the second electrode 008 are located on the same side of the semiconductor laminated layer. The first semiconductor layer 004 can include a high-concentration doping layer that forms ohmic contact with the second electrode 008, and the first semiconductor layer 004 forms ohmic contact with the second electrode 008 through the high-concentration doping layer. The second semiconductor layer 006 can include a high-concentration doping layer that forms ohmic contact with the first electrode 007, and the second semiconductor layer 006 forms ohmic contact with the first electrode 007 through the high-concentration doping layer.

The materials of the first electrode 007 and the second electrode 008 include metals, such as gold (Au), germanium (Ge), beryllium (Be), nickel (Ni), palladium (Pd), zinc (Zn), or their alloys.

The first electrode 007 and the second electrode 008 at least include metals that form ohmic contact with the second semiconductor layer 006 and the first semiconductor layer 004, respectively. For example, when the first semiconductor layer 004 is a P-type semiconductor layer, the second electrode 008 includes an ohmic contact metal layer which is an alloy of gold (Au) and zinc (Zn) or an alloy of gold (Au), germanium (Ge) and nickel (Ni), and the ohmic contact metal layer needs to be subjected to a high-temperature fusion process to form an ohmic contact. When the second semiconductor layer 006 is an N-type semiconductor layer, the first electrode 007 includes an ohmic contact metal layer which is an alloy of gold (Au) and beryllium (Be).

An insulating layer 009 covers the surface and the side walls of the semiconductor laminated layer, and partially covers the surface and side wall of the first electrode 007 and the second electrode 008, and exposes part of the surface of the first electrode 007 and the second electrode 008.

The material of the insulating layer 009 can be a repeating laminated layer of at least one or two different refractive index material layers, such as silicon oxide (SiOₓ), silicon nitride (SiNₓ), magnesium fluoride (MgF₂), etc.

A first pad 010 and a second pad 011 are formed on one side of the first electrode 007 and the second electrode 008 respectively, and formed on one side of the insulating layer 009. The first pad 010 and the second pad 011 are connected to the first electrode 007 and the second electrode 008 respectively.

The first pad 010 and the second pad 011 respectively include titanium (Ti), tungsten (W), platinum (Pt), nickel (Ni), tin (Sn), gold (Au) or their alloys.

The following provides a process for making flip-chip light-emitting element, including steps as follows.
1. A semiconductor laminated layer structure is obtained on a growth substrate through an epitaxial growth process. The growth substrate is a gallium arsenide growth substrate, and the semiconductor laminated layer includes a buffer layer, an etching cut-off layer, a second semiconductor layer (N-type layer), a light-emitting layer, and a first semiconductor layer (P-type layer) stacked in that order on the growth substrate. The semiconductor laminated layer, for example, is an aluminum gallium indium phosphate-based semiconductor laminated layer, the light-emitting layer can emit red light, and the surface of the first semiconductor obtained through the growth process is flat.
2. A transparent substrate is provided, such as a sapphire substrate, including a first surface and a second surface. Photoresist patterns are performed on the first surface of the transparent substrate combined with an etching process to obtain an uneven structure. The etching method can be dry etching or wet etching.
3. A first bonding layer, a silicon oxide layer, is obtained on the first surface of the transparent substrate through a deposition process, and the surface of the first bonding layer is polished through a polishing process to achieve that a surface flatness of the first bonding layer is higher than that of the first surface of the transparent substrate, and the first bonding layer obtained after processing completely covers the patterns of the transparent substrate.
4. The surface of the semiconductor laminated layer is bonded to the first bonding layer.
5. The growth substrate is removed by grinding and etching until the surface of the second semiconductor layer is exposed.
6. Partial areas of the second semiconductor layer and the light-emitting layer are removed from one side of the second semiconductor layer through an etching process to expose the first semiconductor layer, and a first electrode and a second electrode are made on the exposed first semiconductor layer and the second semiconductor layer respectively.
7. An insulating layer, a first pad, and a second pad are manufactured, and a single flip-chip light-emitting element is formed through a cutting process.

### Embodiment 2

As an improved implementation of the embodiment 1, the first surface (i.e., the upper surface) of the semiconductor laminated layer further includes an uneven structure, which can facilitate the extraction of light from the semiconductor laminated layer and improve the light efficiency.

In an embodiment, the uneven structure of the semiconductor laminated layer exhibits a random appearance, such as a random coarsened structure, with a roughness of 0.1-1 micrometers. The coarsened structure facilitates the emission of light from the semiconductor laminated layer to one side of the transparent bonding layer 002, thereby facilitating the extraction of light. In a specific embodiment, the roughness is 100-600 nanometers. The coarsened structure can be formed by dry etching or wet etching.

In an embodiment, the first semiconductor layer 004 of the semiconductor laminated layer includes a GaP layer for forming the uneven structure, with a thickness of 1-8 micrometers. The layer used to form the uneven structure of the first surface (i.e., the upper surface) of the semiconductor laminated layer is doped with magnesium element, with a content of 1E17-5E18 atoms/cm³.

In an embodiment, the height of the uneven structure on the upper surface of the transparent substrate is greater than that on the lower surface of the semiconductor laminated layer.

The transparent substrate has a thicker thickness, and the larger size pattern can be obtained on it surface, which can improve the direction of light more significantly, thus facilitating light output.

In an embodiment, the transparent bonding layer 002 includes at least a first bonding layer 0021 and a second bonding layer 0022. The first bonding layer 0021 is in contact with the first surface of the transparent substrate 001, and the second bonding layer 0022 is located between the semiconductor laminated layer and the first bonding layer 0021. In an embodiment, when the second bonding layer 0022 is in contact with the first surface of the semiconductor laminated layer, the first surface of the transparent substrate 001 has an uneven structure, the first surface of the semiconductor laminated layer also has an uneven structure, and the interface smoothness between the first bonding layer and the second bonding layer is high. Therefore, using the first bonding layer and the second bonding layer to provide a bonding interface can achieve stronger bonding force between the first and second bonding layers under the external force of bonding, thereby improving bonding reliability.

In an embodiment, the thickness T2 of the first bonding layer 0021 is greater than the height H1 of the uneven structure on the first surface of the transparent substrate 001. The thickness T3 of the second bonding layer 0022 is greater than the height H2 of the uneven structure (the height of the coarsened structure) of the first surface of the semiconductor laminated layer. Therefore, the first bonding layer 0021 at least covers the uneven structure on the first surface of the transparent substrate 001, and the second bonding layer 0022 at least covers the uneven structure on the first surface of the semiconductor laminated layer.

The surface of the first bonding layer 0021 facing away from the transparent substrate 001 and the surface of the second bonding layer 0022 facing away from the semiconductor laminated layer are both polished to provide a bonded surface.

The surface of the first bonding layer 0021 in contact with the second bonding layer 0022 is smoother than the first surface of the transparent substrate 001.

The surface of the second bonding layer 0022 in contact with the first bonding layer 0021 is smoother than the first surface of the transparent substrate 001.

In an embodiment, the materials of the first bonding layer 0021 and the second bonding layer 0022 are the same. In a specific embodiment, the first bonding layer 0021 and the second bonding layer 0022 are both silicon oxide. In this way, the interfacial force between the first bonding layer and the second bonding layer is stronger, and the interface bonding is tighter, which can improve bonding reliability.

In an embodiment, the thickness of the first bonding layer 0021 is 1-4 micrometers, the thickness of the second bonding layer 0022 is 1-4 micrometers, and the sum of the two thicknesses is 2-8 micrometers. As a specific embodiment, the thickness of the first bonding layer 0021 is 1-3 micrometers, and the thickness of the second bonding layer 0022 is 1-3 micrometers.

The following provides a process for making a flip-chip light-emitting element, including steps as follows.
1. A semiconductor laminated layer structure is obtained on a growth substrate through an epitaxial growth process. The growth substrate is a gallium arsenide growth substrate, and the semiconductor laminated layer includes a buffer layer, an etching cut-off layer, a second semiconductor layer (N-type layer), a light-emitting layer, and a first semiconductor layer (P-type layer) stacked in that order on the growth substrate. The semiconductor laminated layer, for example, is an aluminum gallium indium phosphate-based semiconductor laminated layer, and the light-emitting layer can emit red light.
2. The surface of the first semiconductor layer is performed with an etching process to form a coarsened uneven structure, and the etching process can be dry etching or wet etching. In a specific embodiment, the etching process is wet etching, for example, the coarsened uneven structure has a height of 0.4-0.6 micrometers.
3. A second bonding layer and a silicon oxide layer are obtained on the surface of the first semiconductor layer through a deposition process. Through a polishing process, the flatness of the silicon oxide layer is higher than that of the surface of the first semiconductor layer, and the second bonding layer obtained after polishing completely covers the coarsened structure of the surface of the first semiconductor layer.
4. A transparent substrate is provided, such as a sapphire substrate, including a first surface and a second surface. Photoresist patterns are performed on the first surface of the transparent substrate combined with an etching process to obtain a pattern structure. The etching method can be dry etching or wet etching.
5. A first bonding layer is obtained on the first surface of the transparent substrate through a deposition process, and the surface roughness of the first bonding layer is lower than that of the first surface of the transparent substrate through a polishing process, and the first bonding layer obtained after polishing completely covers the pattern of the transparent substrate.
6. The first surface of the semiconductor laminated layer is bonded to the first surface of the first bonding layer.
7. The growth substrate is removed through grinding combined with etching to expose the surface of the second semiconductor layer.
8. Partial areas of the first semiconductor layer and the light-emitting layer are removed from one side of the second semiconductor layer through an etching process to expose the first semiconductor layer, and a first electrode and a second electrode are made on the exposed first semiconductor layer and the second semiconductor layer respectively.
9. An insulating layer, a first pad, and a second pad are manufactured are manufactured, and a single flip-chip light-emitting element is formed through a cutting process.

### Embodiment 3

As an alternative implementation of the embodiment 2, due to the stable chemical properties of the sapphire substrate, which is difficult to etch, the disclosure proposes another technical solution as follows.

As shown in FIG. 4, the flip-chip light-emitting element includes a transparent substrate 001, an intermediate layer 0011, a transparent bonding layer 002, and a semiconductor laminated layer arranged from top to bottom. The intermediate layer 0011 is located between the transparent substrate 001 and the transparent bonding layer 002, and the transparent bonding layer 002 is located between the intermediate layer 0011 and the semiconductor laminated layer. The semiconductor laminated layer includes a first semiconductor layer 004, a light-emitting layer 005, and a second semiconductor layer 006 arranged from top to bottom.

Specifically, the transparent substrate 001 is a flat substrate, and the first surface (i.e., the lower surface) of the transparent substrate 001 is flat, without forming an uneven structure.

The first surface of the transparent substrate 001 and the transparent bonding layer 002 is disposed with an intermediate layer 0011 therebetween. The intermediate layer 0011 has a first surface, and the first surface of the intermediate layer 0011 is in contact with the transparent bonding layer 002. The first surface of the intermediate layer 0011 has an uneven structure, such as a random coarsened structure, and the material of the intermediate layer 0011 is more easily etched, with an etching rate exceeding that of the transparent substrate 001, which can increase the etching rate, thereby improving the process efficiency.

In an embodiment, a refractive index of the intermediate layer 0011 is greater than that of the transparent bonding layer 002.

In an embodiment, the material for the intermediate layer 0011 is silicon nitride, thallium oxide, indium tin oxide, or indium zinc oxide.

A thickness of the intermediate layer 0011 can be 1-5 micrometers.

In an embodiment, the first surface (i.e., upper surface) of the semiconductor laminated layer includes an uneven structure.

In an embodiment, the uneven structure of the semiconductor laminated layer exhibits a random appearance, such as a random coarsened structure, with a roughness of 0.1-1 micrometers. The coarsened structure facilitates the emission of light from the semiconductor laminated layer to one side of the transparent bonding layer 002, thereby facilitating the extraction of light. In a specific embodiment, the roughness is 100-600 nanometers. The coarsened structure can be formed by dry etching or wet etching.

The transparent bonding layer 002 includes a first bonding layer 0021 and a second bonding layer 0022. The first bonding layer 0021 is located above the intermediate layer 0011, and the second bonding layer 0022 is located above the first bonding layer 0021. The first bonding layer 0021 is in contact with the first surface of the intermediate layer 0011, and the second bonding layer 0022 is in contact with the first surface of the semiconductor laminated layer. The first bonding layer and the second bonding layer provide a bonding interface, and the smoothness of the interface between the first bonding layer and the second bonding layer can be achieved through polishing process. Under the external force of bonding, the bonding force between the first bonding layer and the second bonding layer is stronger, thereby improving bonding reliability.

In an embodiment, the thickness T4 of the first bonding layer 0021 is greater than the height H4 of the uneven structure of the first surface of the intermediate layer 0011. The thickness T5 of the second bonding layer 0022 is greater than the height H5 of the uneven structure (the height of the coarsened structure) of the first surface of the semiconductor laminated layer. Therefore, the first bonding layer 0021 at least covers the uneven structure on the first surface of the intermediate layer 0011, and the second bonding layer 0022 at least covers the uneven structure on the first surface of the semiconductor laminated layer.

In an embodiment, the materials of the first bonding layer 0021 and the second bonding layer 0022 are the same.

In an embodiment, the first bonding layer 0021 and the second bonding layer are both silicon oxide. In this way, the interfacial force between the first bonding layer and the second bonding layer is stronger, and the interface bonding is tighter, which can improve bonding reliability.

In an embodiment, the thickness of the first bonding layer 0021 is 1-4 micrometers, the thickness of the second bonding layer 0022 is 1-4 micrometers, and the sum of the thicknesses of the first bonding layer 0021 and the second bonding layer 0022 is 2-8 micrometers. As a specific embodiment, the thickness of the first bonding layer 0021 is 1-3 micrometers, and the thickness of the second bonding layer 0022 is 1-2 micrometers.

### Embodiment 4

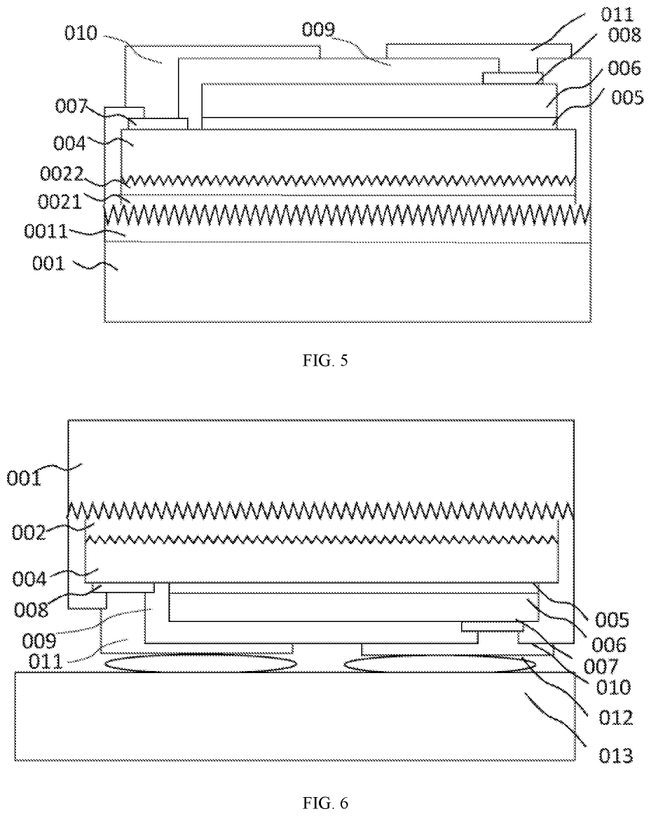

As an alternative implementation of the embodiments 1, 2, and 3, it is a front-mounted light-emitting element having the characteristic of radiating light from a semiconductor laminated layer and passing through an insulating layer on one side away from the transparent substrate of the semiconductor laminated layer, an insulating layer around the side walls of the semiconductor laminated layer, and the side walls of the transparent substrate. Specifically, as shown in FIG. 5, the front-mounted light-emitting element includes a transparent substrate 001, a transparent bonding layer 002, and a semiconductor laminated layer arranged from bottom to top. The semiconductor laminated layer includes a first semiconductor layer 004, a light-emitting layer 005, a second semiconductor layer 006, a first electrode 007, a second electrode 008, a transparent insulating layer 009, a first pad 010, and a second pad 011 arranged from bottom to top.

The first pad 010 and the second pad 011 can be connected by wiring to achieve the installation of the front-mounted LED on a packaging substrate or a circuit substrate.

### Embodiment 5

FIG. 6 illustrates a schematic structural diagram of a light-emitting device according to the embodiment 5 of the disclosure. The light-emitting device includes a substrate 013, the flip-chip LED chip of at least one of the aforementioned embodiments 1 to 3 on the substrate 013, and a metal connection layer 012, such as a tin connection layer, located between the substrate 013 and the flip-chip LED chip.

The light-emitting device can but is not limited to the fields of lamps, display screens, etc.

What is claimed is:

1. A semiconductor light-emitting element, comprising: a transparent substrate, a transparent bonding layer, and a semiconductor laminated layer;
wherein the transparent bonding layer is located between the transparent substrate and the semiconductor laminated layer;
wherein the semiconductor laminated layer comprises a first semiconductor layer, a light-emitting layer, and a second semiconductor layer;
wherein the transparent substrate has a first surface facing towards the semiconductor laminated layer, and the first surface of the transparent substrate has an uneven structure;
wherein the transparent bonding layer comprises a first bonding layer, the first bonding layer is in contact with the first surface of the transparent substrate, and a refractive index of the first bonding layer is lower than that of the transparent substrate.

2. The semiconductor light-emitting element as claimed in claim 1, wherein the transparent bonding layer further comprises a second bonding layer, the second bonding layer is located between the first bonding layer and the semiconductor laminated layer, and the second bonding layer is in contact with the first bonding layer.

3. The semiconductor light-emitting element as claimed in claim 2, wherein the second bonding layer and the first bonding layer are made of a same material.

4. The semiconductor light-emitting element as claimed in claim 2, wherein the first bonding layer and the second bonding layer both are silicon oxide layers.

5. The semiconductor light-emitting element as claimed in claim 4, wherein a thickness of the first bonding layer and a thickness of the second bonding layer both are in a range of 1-4 micrometers.

6. The semiconductor light-emitting element as claimed in claim 1, wherein a height of the uneven structure of the first surface of the transparent substrate is in a range of 0.1-3 micrometers.

7. The semiconductor light-emitting element as claimed in claim 2, wherein the semiconductor laminated layer has a first surface facing towards the transparent substrate, and the first surface of the semiconductor laminated layer has an uneven structure.

8. The semiconductor light-emitting element as claimed in claim 7, wherein a height of the uneven structure of the first surface of the semiconductor laminated layer is in a range of 0.1-1 micrometer.

9. The semiconductor light-emitting element as claimed in claim 7, wherein a height of the uneven structure of the first surface of the transparent substrate is greater than a height of the uneven structure of the first surface of the semiconductor laminated layer.

10. The semiconductor light-emitting element as claimed in claim 7, wherein a surface of the first bonding layer in contact with the second bonding layer is smoother than the first surface of the transparent substrate.

11. The semiconductor light-emitting element as claimed in claim 10, wherein a surface of the second bonding layer in contact with the first bonding layer is smoother than the first surface of the semiconductor laminated layer.

12. The semiconductor light-emitting element as claimed in claim 1, wherein the uneven structure of the transparent substrate comprises a plurality of patterned structures arranged in an array, a spacing between adjacent two patterned structures of the plurality of patterned structures is in a range of 0.1-3 micrometers, and a bottom width of each of the plurality of patterned structures is in a range of 0.1-4 micrometers.

13. The semiconductor light-emitting element as claimed in claim 7, wherein the uneven structure of the semiconductor laminated layer is a coarsened structure, and a roughness of the coarsened structure is in a range of 0.1-1 micrometer.

14. A semiconductor light-emitting element, comprising: a transparent substrate, an intermediate layer, a transparent bonding layer, and a semiconductor laminated layer;
wherein the intermediate layer is located between the transparent substrate and the transparent bonding layer;
wherein the transparent bonding layer is located between the intermediate layer and the semiconductor laminated layer;
wherein the semiconductor laminated layer comprises a first semiconductor layer, a light-emitting layer, and a second semiconductor layer;
wherein the transparent substrate is a flat substrate, the intermediate layer has a first surface facing towards the semiconductor laminated layer, and the first surface of the intermediate layer has an uneven structure;
wherein a refractive index of the intermediate layer is higher than that of the transparent bonding layer.

15. The semiconductor light-emitting element as claimed in claim 14, wherein the semiconductor laminated layer has a first surface facing towards the transparent substrate, and the first surface of the semiconductor laminated layer has an uneven structure.

16. The semiconductor light-emitting element as claimed in claim 15, wherein the transparent bonding layer comprises a first bonding layer and a second bonding layer, the first bonding layer is in contact with the first surface of the intermediate layer, and the second bonding layer is located between the first bonding layer and the first surface of the semiconductor laminated layer.

17. The semiconductor light-emitting element as claimed in claim 16, wherein the first bonding layer and the second bonding layer of the transparent bonding layer are made of a same material.

18. The semiconductor light-emitting element as claimed in claim 16, wherein the first bonding layer at least covers the uneven structure of the intermediate layer, and a thickness of the first bonding layer is greater than a height of the uneven structure of the intermediate layer; the second bonding layer at least covers the uneven structure of the semiconductor laminated layer, and a thickness of the second bonding layer is greater than a height of the uneven structure of the semiconductor laminated layer.

19. The semiconductor light-emitting element as claimed in claim 16, wherein a surface of the first bonding layer in contact with the second bonding layer is smoother than the first surface of the intermediate layer and the first surface of the semiconductor laminated layer.

20. A light-emitting device, comprising the semiconductor light-emitting element as claimed in claim 1.
